(19) United States
(12) Patent Application Publication
(10) Pub. No.: US 2024/0315138 A1
(43) Pub. Date: Sep. 19, 2024

(54) ULTRASONIC TRANSDUCER

(71) Applicant: Murata Manufacturing Co., Ltd., Nagaokakyo-shi (JP)

(72) Inventors: Yasuhiro TADA, Nagaokakyo-shi (JP); Tomoaki MATSUSHITA, Nagaokakyo-shi (JP)

(21) Appl. No.: 18/679,516

(22) Filed: May 31, 2024

Related U.S. Application Data
(63) Continuation of application No. PCT/JP2022/033994, filed on Sep. 12, 2022.

(30) Foreign Application Priority Data
Dec. 20, 2021 (JP) 2021-205946

(51) Int. Cl. H10N 30/88; B06B 1/06; H10N 30/853; H10N 30/87

(52) U.S. Cl. CPC H10N 30/883; B06B 1/06; H10N 30/8554; H10N 30/875; H10N 30/877

(57) ABSTRACT

An ultrasonic transducer includes a case, a piezoelectric element, and a filler. The case has a bottomed cylindrical shape including a bottom portion and a side wall portion. The piezoelectric element is attached to the bottom portion of the case. The filler fills at least a portion in the case adjacent to or in a vicinity of the bottom portion and covers the piezoelectric element. A cavity is provided in a portion of the side wall portion adjacent to or in a vicinity of the bottom portion. The filler includes a foamed silicone resin with a closed-cell foam structure. The cavity is sealed with the filler.

### CROSS REFERENCE TO RELATED APPLICATIONS

This application claims the benefit of priority to Japanese Patent Application No. 2021-205946 filed on Dec. 20, 2021 and is a Continuation Application of PCT Application No. PCT/JP2022/033994 filed on Sep. 12, 2022. The entire contents of each application are hereby incorporated herein by reference.

### BACKGROUND OF THE INVENTION

### 1. Field of the Invention

The present invention relates to ultrasonic transducers.

### 2. Description of the Related Art

Japanese Unexamined Patent Application Publication No. 2006-345271 discloses the structure of an ultrasonic transceiver including a bottomed cylindrical case and a piezoelectric element. The piezoelectric element is attached to a bottom surface of the case. A cavity is provided in a side surface of the case. An acoustic absorbent made of foamed silicone or the like is placed on an upper surface of the piezoelectric element. A sealing material made of a silicone material or a urethane material fills a portion above the acoustic absorbent in the case. The cavity is filled with a flexible filler, such as a silicone material or a urethane material.

When the filler that fills the cavity and the acoustic absorbent that covers the piezoelectric element are formed separately from each other, the number of components and the manufacturing process complexity increase.

### SUMMARY OF THE INVENTION

Example embodiments the present invention provide ultrasonic transducers each having a simpler structure by reducing a number of components and a manufacturing process complexity.

An ultrasonic transducer according to an example embodiment of the present invention includes a case, a piezoelectric element, and a first filler. The case has a bottomed cylindrical shape including a bottom portion and a side wall portion. The piezoelectric element is attached to the bottom portion of the case. The first filler fills at least a portion in the case adjacent to or in a vicinity of the bottom portion and covers the piezoelectric element. A cavity is provided in a portion of the side wall portion adjacent to or in a vicinity of the bottom portion. The first filler includes a foamed silicone resin with a closed-cell foam structure. The cavity is sealed with the first filler.

According to example embodiments of the present invention, a simpler structure is able to be achieved by reducing a number of components and a manufacturing process complexity of the ultrasonic transducer.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a vertical cross-sectional view of an ultrasonic transducer according to an example embodiment of the present invention.

FIG. 2 is a vertical cross-sectional view of the ultrasonic transducer in FIG. 1 taken along line II-II.

FIG. 3 is a bottom view of an ultrasonic transducer according to an example embodiment of the present invention, as viewed from the bottom.

FIG. 4 is a graph illustrating the relationship between the foaming ratio of a first filler and the overall sensitivity of the ultrasonic transducer obtained in accordance with the results of a second experimental example.

FIG. 5 is a vertical cross-sectional view of an ultrasonic transducer according to a modification of an example embodiment of the present invention.

### DETAILED DESCRIPTION OF THE EXAMPLE EMBODIMENTS

Example embodiments of the present invention will be described in detailed below with reference to the accompanying drawings.

An ultrasonic transducer according to an example embodiment of the present invention will be described with reference to the drawings. In the following descriptions of example embodiments of the present invention, the same or corresponding portions in the drawings are denoted by the same reference numerals and the descriptions thereof are omitted.

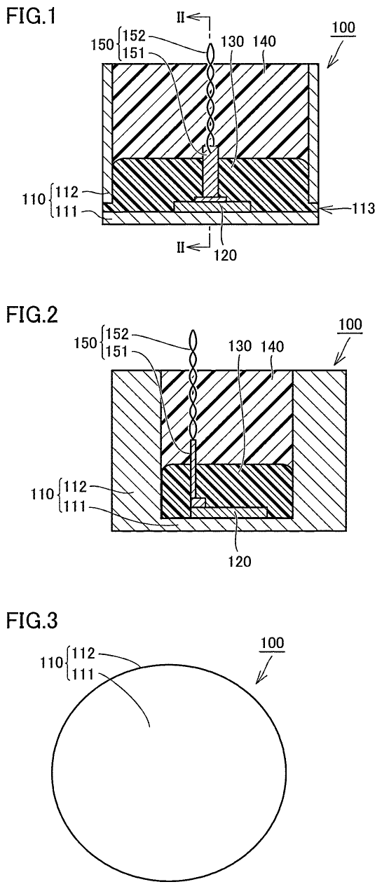

FIG. 1 is a vertical cross-sectional view of the ultrasonic transducer according to the present example embodiment of the present invention. FIG. 2 is a vertical cross-sectional view of the ultrasonic transducer in FIG. 1 taken along line II-II. FIG. 3 is a bottom view of the ultrasonic transducer according to the present example embodiment of the present invention, as viewed from the bottom.

As illustrated in FIGS. 1 to 3, the ultrasonic transducer 100 according to the present example embodiment includes a bottomed-cylindrical case 110, a piezoelectric element 120, a first filler 130, and a second filler 140.

As illustrated in FIGS. 1 to 3, the case 110 includes a bottom portion 111 and a side wall portion 112. As illustrated in FIG. 3, the bottom portion 111 has a circular or substantially circular plate shape. However, the shape of the bottom portion 111 is not limited to a circular or substantially circular plate shape and may have a rectangular or substantially rectangular plate shape or a polygonal or substantially polygonal plate shape. The diameter of the bottom portion 111 is, for example, about 14.0 mm.

The side wall portion 112 extends upward from the circumferential edge of the bottom portion 111. The height of the case 110 from the outer bottom surface of the bottom portion 111 located on the outer surface of the case 110 to the upper end of the side wall portion 112 is, for example, about 9.0 mm.

A cavity 113 is provided in a portion of the side wall portion 112 adjacent to or in a vicinity of to the bottom portion 111. The cavity 113 extends in a circumferential direction of the case 110. In the present example embodiment, the cavity 113 extends along the upper surface of the bottom portion 111. The height of the cavity 113 is, for example, about 1 mm, and the length of the cavity 113 in the circumferential direction is, for example, about 5 mm. It is possible to decrease the angle range of the directional characteristics of the ultrasonic transducer 100 in the vertical direction by increasing the length of the cavity 113 in the circumferential direction.

The inner width of the case 110 is maximum in the vertical cross section of the ultrasonic transducer 100 according to the present example embodiment illustrated in FIG. 1 that passes through a central axis of the bottom portion 111. The vertical cross section is also referred to simply below as the main cross section. The shape of the inner side surface of the case 110 in the direction of the central axis of the bottom portion 111 is, for example, rectangular or substantially rectangular or oval or substantially oval.

The case 110 is made of a conductive material. In the present example embodiment, the case 110 is made of, for example, an aluminum alloy. The material of the case 110 is not limited to a conductive material and may be, for example, an insulating material. The case 110 is formed by, for example, forging.

The piezoelectric element 120 includes a piezoelectric body made of, for example, a ceramic. In the present example embodiment, the piezoelectric body included in the piezoelectric element 120 is made of, for example, a PZT (lead zirconate titanate) ceramic. However, the material of the piezoelectric body included in the piezoelectric element 120 is not limited to a PZT ceramic and may be another piezoelectric material. A unimorph piezoelectric vibrator is provided by attaching the piezoelectric body of the piezoelectric element 120 to the bottom portion 111. The piezoelectric element 120 may be a bimorph piezoelectric vibrator or a multimorph piezoelectric vibrator.

The piezoelectric element 120 includes a pair of electrodes. When a voltage is applied to the pair of electrodes, the piezoelectric element 120 is driven and vibrates. When the piezoelectric element 120 vibrates, the bottom portion 111 vibrates.

In addition, when the bottom portion 111 of the case 110 vibrates in response to receiving an ultrasonic wave from the outside, the piezoelectric element 120 also vibrates in response to this vibration. When an electric charge is generated due to vibration of the piezoelectric element 120, an ultrasound wave is converted into an electrical signal by the piezoelectric element 120. The electrical signal is transmitted to the outside through the pair of electrodes.

The external shape of the ultrasonic transducer 100 as viewed from the opening end of the case 110 opposite to the bottom portion 111 is not particularly limited and may be, for example, circular, substantially circular, rectangular, substantially rectangular, polygonal, or substantially polygonal.

As illustrated in FIG. 1, in the main cross section of the ultrasonic transducer 100 according to the present example embodiment of the present invention, the piezoelectric element 120 is disposed in or substantially in the middle in the radial direction of the case 110.

The piezoelectric element 120 is attached to the bottom portion 111 in the case 110. In the present example embodiment, the piezoelectric element 120 is adhered to the bottom portion 111 by, for example, an epoxy resin.

As illustrated in FIGS. 1 and 2, the first filler 130 fills at least a portion in the case 110 adjacent to or in a vicinity of the bottom portion 111 and covers the piezoelectric element 120. In the present example embodiment, the first filler 130 fills the lower portion adjacent to or in a vicinity of the bottom portion 111 in the case 110. The cavity 113 is sealed with the first filler 130.

The first filler 130 includes, for example, a foamed silicone resin with a closed-cell foam structure. The first filler 130 includes, for example, an addition-reaction silicone resin. The first filler 130 can be formed by, for example, potting. In the potting, a liquid silicone resin is applied to the bottom portion 111 of the case 110 and the piezoelectric element 120, and the liquid silicone resin is cured. As a result, the first filler 130 can be in close contact with the piezoelectric element 120 regardless of the shape of the piezoelectric element 120.

The closed-cell foam structure of the first filler 130 may be formed by, for example, a gas generated in a curing reaction when the liquid silicone resin is cured or may be formed by mixing a gas into the liquid silicone resin in advance. The foaming ratio of the foamed silicone foam included in the first filler 130 is, for example, not less than about 1.5 and not more than about 2.0. The foaming ratio in a foam including a resin and a gas is represented by ρ1/ρ2 (ρ1: density of resin before mixture with gas, ρ2: density of resin after mixture with gas).

As illustrated in FIGS. 1 and 2, the second filler 140 is injected to cover the first filler 130 in the case 110. The second filler 140 fills an upper portion located above the first filler 130 in the case 110.

The second filler 140 includes, for example, a condensation-reaction silicone resin. The second filler 140 may be made of another resin material having a lower elastic modulus than the first filler 130, such as, for example, a urethane resin.

As illustrated in FIGS. 1 and 2, the ultrasonic transducer 100 according to the present example embodiment further includes a conductive portion 150. The conductive portion 150 and the pair of electrodes described above are electrically connected to each other. The conductive portion 150 includes a circuit board portion 151 and two wiring portions 152. The circuit board portion 151 passes through the first filler 130. In the present example embodiment, the circuit board portion 151 is defined by, for example, a flexible printed circuit (FPC) including a resin sheet on which wiring is printed. In the present example embodiment, for example, the resin sheet is made of a polyimide and the wiring is made of copper. The wiring of the circuit board portion 151 and the electrodes provided on the piezoelectric element 120 are connected to each other by a conductive adhesive. The adhesive may be, for example, a mixture of an epoxy resin and solder.

The two wiring portions 152 are electrically connected to the wiring of the circuit board portion 151. In the present example embodiment, for example, the two wiring portions 152 and the wiring of the circuit board portion 151 are connected to each other by soldering. The two wiring portions 152 extend from the second filler 140 to the outside of the ultrasonic transducer 100.

One of the two wiring portions 152 is electrically connected to one of the pair of electrodes via the circuit board portion 151. The other of the two wiring portions 152 is electrically connected to the other of the pair of electrodes via the circuit board portion 151.

In the present example embodiment, for example, the two wiring portions 152 extend to the outside of the ultrasonic transducer 100 as a twisted pair of lead wires.

### Experimental Examples

Here, a first experimental example of an example embodiment of the present invention in which the relationship between the foaming ratio of the first filler and the reverberation time of the ultrasonic transducer was examined will be described. Experimental conditions will be described below. In an ultrasonic transducer having the same or substantially the same component structure as the ultrasonic transducer 100 according to the present example embodiment, the reverberation time of the ultrasonic transducer was measured while the foaming ratio of the first filler was changed.

Specifically, the piezoelectric element 120 was driven by connecting a power supply to the conductive portion 150 of the ultrasonic transducer and applying 16 waves of a pulse voltage of about 200 Vpp to the piezoelectric element 120. The elapsed time from when the voltage application by the power supply was stopped until the falling waveform of driving vibration of the piezoelectric element 120 in a signal obtained by amplifying the detection signal of the ultrasonic transducer to about 48 dB became about 2 V or less was determined as the reverberation time in this experimental example. The voltage value was measured by an oscilloscope.

Table 1 summarizes the relationship between the foaming ratio of the first filler and the reverberation time of the ultrasonic transducer in accordance with the results of the first experimental example.

TABLE 1

| Foaming Ratio | 1.3 | 1.65 | 1.8 | 2.0 | 3.0 |
|---|---|---|---|---|---|
| Q value of Main | 26.5 | 37.0 | 41.6 | 47.6 | 77.8 |
| Vibration | | | | | |
| Q value of Spurious | 31.2 | 35.4 | 37.2 | 39.5 | 51.4 |
| Vibration | | | | | |
| Reverberation Time | 1.16 | 1.27 | 1.32 | 1.38 | 1.70 |
| (ms) | | | | | |

Main vibration is resonant vibration at the driving frequency of the piezoelectric element 120. Spurious vibration is vibration at a resonant frequency that differs from the driving frequency of the piezoelectric element 120.

As can be seen from Table 1, as the foaming ratio of the first filler increased, the Q value of main vibration increased, the Q value of spurious vibration also increased, and the reverberation time increased. This is because, as the foaming ratio of the first filler increases, the volume occupied by the resin in the first filler decreases, and the damping effect of the first filler decreases.

When the reverberation time exceeds about 1.4 ms, desired short-distance detection performance of the ultrasonic transducer cannot be maintained. In accordance with the experimental results, it was discovered that the foaming ratio of the first filler is to be about 2 or less to maintain the Q value of spurious vibration at about 39.5 or less and the reverberation time at about 1.4 ms or less, for example.

Next, a second experimental example in which the relationship between the foaming ratio of the first filler and the overall sensitivity of the ultrasonic transducer was examined will be described. Experimental conditions will be described below. In an ultrasonic transducer having the same or substantially the same component structure as the ultrasonic transducer 100 according to the present example embodiment, the overall sensitivity of the ultrasonic transducer was measured while the foaming ratio of the first filler was changed.

Specifically, the piezoelectric element 120 was driven by connecting the power supply to the conductive portion 150 of the ultrasonic transducer and applying 16 waves of a pulse voltage of about 200 Vpp to the piezoelectric element 120. A polyvinyl carbonate pole having a diameter of about 75 mm and a height of about 1 m was set as a detection object. The ultrasonic transducer was disposed at a position about 60 cm away from the pole such that the bottom portion 111 faced a portion of the pole that was about 60 cm high. The maximum voltage value of a reflected waveform of the signal obtained by amplifying the detection signal of the ultrasonic transducer to about 48 dB was determined as the overall sensitivity in this experimental example. The voltage value was measured by an oscilloscope.

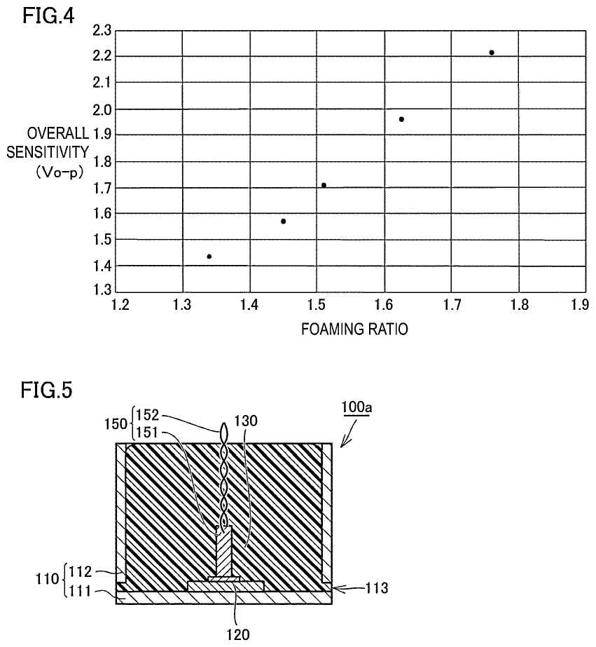

FIG. 4 is a graph showing the relationship between the foaming ratio of the first filler and the overall sensitivity of the ultrasonic transducer obtained in accordance with the results of the second experimental example. In FIG. 4, the vertical axis represents the overall sensitivity (Vo-p) of the ultrasonic transducer, and the horizontal axis represents the foaming ratio of the first filler.

As illustrated in FIG. 4, as the foaming ratio of the first filler increases, the overall sensitivity of the ultrasonic transducer increases. As the foaming ratio of the first filler increases, the angular range of directional characteristics of the ultrasonic transducer in the vertical direction becomes narrow. In general, when the overall sensitivity is less than about 1.6, the long-distance detection performance of the ultrasonic transducer decreases. In accordance with the experimental results, for example, it was discovered that the foaming ratio of the first filler is to be not less than about 1.5 to maintain the overall sensitivity (Vo-p) at about 1.6 or more.

In accordance with the results of the first and second experimental examples, for example, it was discovered that the foaming ratio of the first filler is to be not less than about 1.5 and not more than about 2 to ensure both the short-distance detection performance and the long-distance detection performance of the ultrasonic transducer.

The ultrasonic transducer 100 according to the present example embodiment includes the case 110, the piezoelectric element 120, and the first filler 130. The case 110 has a bottomed cylindrical shape including the bottom portion 111 and the side wall portion 112. The piezoelectric element 120 is attached to the bottom portion 111 in the case 110. The first filler 130 fills at least a portion in the case 110 adjacent to or in a vicinity of the bottom portion 111 and covers the piezoelectric element 120. The cavity 113 is provided in a portion of the side wall portion 112 adjacent to or in a vicinity of the bottom portion 111. The first filler 130 includes a foamed silicone resin with a closed-cell foam structure. The cavity 113 is sealed with the first filler 130. As a result, a simpler structure can be achieved by reducing the number of components and the manufacturing process complexity of the ultrasonic transducer 100. In addition, the design and the water resistance of the cavity 113 can be improved by the cavity 113 being sealed with a foamed silicone resin with a closed-cell foam structure.

In the ultrasonic transducer 100 according to the present example embodiment, the foaming ratio of the first filler 130 is not less than about 1.5 and not more than about 2.0. As a result, both the short-distance detection performance and the long-distance detection performance of the ultrasonic transducer 100 can be ensured.

The ultrasonic transducer 100 according to the present example embodiment further includes the second filler 140 injected to cover the first filler 130 in the case 110. The first filler 130 includes an addition-reaction silicone resin. The second filler 140 includes a condensation-reaction silicone resin. This can reduce or prevent curing of the addition-reaction silicone resin of the second filler 140 from being inhibited at the interface between the first filler 130 and the second filler 140. If the condensation-reaction silicone resin is injected before the addition-reaction silicone resin is injected, the curing of the addition-reaction silicone resin may be inhibited.

The second filler 140 does not necessarily have to be provided. FIG. 5 is a vertical cross-sectional view of an ultrasonic transducer according to a modification of an example embodiment of the present invention. As illustrated in FIG. 5, in an ultrasonic transducer 100a according to the present modification, the second filler 140 is not provided, and the first filler 130 fills the inside of the case 110.

Since the second filler 140 is not provided in the ultrasonic transducer 100a according to the present modification, a simpler structure than the ultrasonic transducer 100 can be achieved by reducing the number of components and the manufacturing process complexity.

In the description of the example embodiments and modification described above, structures that can be combined may be combined with each other.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An ultrasonic transducer comprising:
a bottomed cylindrical case including a bottom portion and a side wall portion;
a piezoelectric element attached to the bottom portion of the case; and
a first filler that fills at least a portion in the case adjacent to or in a vicinity of the bottom portion and covers the piezoelectric element; wherein
a cavity is provided in a portion of the side wall portion adjacent to or in a vicinity of the bottom portion;
the first filler includes a foamed silicone resin with a closed-cell foam structure; and
the cavity is sealed with the first filler.

2. The ultrasonic transducer according to claim 1, wherein a foaming ratio of the first filler is not less than about 1.5 and not more than about 2.0.

3. The ultrasonic transducer according to claim 1, further comprising:
a second filler covering the first filler in the case; wherein
the first filler includes an addition-reaction silicone resin; and
the second filler includes a condensation-reaction silicone resin.

4. The ultrasonic transducer according to claim 1, wherein the bottom portion has a circular or substantially circular plate shape.

5. The ultrasonic transducer according to claim 1, wherein the bottom portion has a diameter of about 14 mm.

6. The ultrasonic transducer according to claim 1, wherein a height of the case is about 9.0 mm.

7. The ultrasonic transducer according to claim 1, wherein a dimension of the recess in a circumferential direction of the case is about 5 mm, and a dimension of the recess in a height direction of the case is about 1 mm.

8. The ultrasonic transducer according to claim 1, wherein the case is made of a conductive material.

9. The ultrasonic transducer according to claim 8, wherein the conductive material includes an aluminum alloy.

10. The ultrasonic transducer according to claim 1, wherein the piezoelectric element includes a piezoelectric body made of ceramic.

11. The ultrasonic transducer according to claim 10, wherein the ceramic is lead zirconate titanate.

12. The ultrasonic transducer according to claim 1, wherein the piezoelectric element includes a pair of electrodes.

13. The ultrasonic transducer according to claim 1, wherein the piezoelectric element is positioned in or substantially in a middle in a radial direction of the case.

14. The ultrasonic transducer according to claim 1, wherein the piezoelectric element is adhered to the bottom portion by an epoxy resin.

15. The ultrasonic transducer according to claim 12, further comprising a conductive portion electrically connected to the pair of electrodes.

16. The ultrasonic transducer according to claim 15, wherein the conductive portion includes a circuit board portion and two wiring portions.

17. The ultrasonic transducer according to claim 16, wherein the circuit board portion is defined by a flexible printed circuit including a resin sheet on which wiring is printed.

18. The ultrasonic transducer according to claim 17, wherein the resin sheet includes a polyimide.
